(19) United States
(12) Patent Application Publication
(10) Pub. No.: US 2005/0143047 A1
(43) Pub. Date: Jun. 30, 2005

(54) Low noise and distortion adapter and system for providing audio output signals from the auxiliary SDARS radio to the in-vehicle AM/FM radio

(76) Inventors: Hyuk-Joon Kwon, KyungKi-Do (KR); Iouri Sinelnikov, Seoul (KR); Seok-Sang Lee, Seoul (KR); Du-Seok Won, Seoul (KR)

Correspondence Address: DYKEMA GOSSETT PLLC, FRANKLIN SQUARE, THIRD FLOOR WEST, 1300 I STREET, NW, WASHINGTON, DC, 20005, US

(21) Appl. No.: 10/979,884

(22) Filed: Nov. 3, 2004

(30) Foreign Application Priority Data
Nov. 5, 2003 (KR) 10-2003-0078057

(51) Int. Cl. H04B 1/06; H05K 11/02

(52) U.S. Cl. 455/345

(57) ABSTRACT

An adapter is provided link between auxiliary Satellite Digital Audio Radio Services Receiver and in-dash AM/FM car radio. The adapter proposed in this invention combines together a wireless FM communication links and a hard-wired RF link. The adapter can be easily reconfigured through user interface and implemented in two modes. The adapter structure and two modes application variety did not depend on analog or digital audio signals which have to be transmitted from SDARS receivers (Satellite Digital Audio Radio Services Receiver) to the car stereo through in-dash AM/FM radio.

### BACKGROUND OF THE INVENTION

1. Field of the Invention

The present invention relates to the in-vehicle audio systems, and more particularly, to an adapter that allows an auxiliary novel SDARS (Satellite Digital Audio Radio Services) receiver to be connected to the in-vehicle high-fidelity sound systems through a factory-installed in-dash AM/FM radio.

2. Description of Related Art

Some SDARS receivers (Satellite Digital Audio Radio Services Receiver) are added on to an existing in-vehicle audio system as novel aftermarket (not OEM) satellite-delivered radio. Add-on components have to be communicated with in-dash AM/FM head unit radio through the various kinds of adapters. Brand name, called AM/FM head units, allow to connect any auxiliary source (cassette, MP3, CD, etc.) with RCA outputs to the AUX audio input. Just the auxiliary source must have a standard level of output voltage, or a volume control to adjust output level.

If SDARS radio is connected to car stereo via the AUX input, hard-wired system does not have any quality losses of audio signal, but a direct ground connection has a lot off problems. RCA cable and common power line are picking up some kind of in-vehicle electrical interference: either alternator “whine” or popping noise (ignition, sparkplugs), or the “hiss” (white) noise and so on. The best way to fix is using a complementary GLI (Ground Loop Isolator) device with optional standard chock inductor of 10 millihenry hooked in series with the power line to the each SDARS, AM/FM radio and head-end car audio devices. Howevr, audio performance still will be so sensitive to the in-vehicle wire routing and chassis (ground) connection quality.

Other way for in-vehicle audio system integration is a short-range wireless communication links. A lot of wireless frequency modulated (FM) systems were described in prior art to eliminate hard wiring and electrical conductors.

This conventional technique is disclosed in, for example, U.S. Pat. No. 5,970,390 and U.S. Pat. No. 6,493,546 B2. System has additional scanning receiver seeking an empty or unused frequency within a FM broadcasting band and having the lowest noise floor. Automatically detected empty frequency is set to the FM transmission. This kind of adapters needed a microcomputers control, are so bulky, expensive and can avoid only interference with commercial broadcast FM signals, but not to overcome FM transmission limitation.

The fundamentals of FM transmission haven't changed since the 1950s, and it's definitely old school technology. The sound quality will be limited by the inherent limitations of FM radio itself: FM tuner only has a frequency response up to 15 kHz, signal-to-noise ratio around 60 db, limited dynamic range, reduced stereo channel separation, etc. In the road area of high environmental noise, such as vehicle engine ignition VHF noise, commercial FM broadcasts station signals, precipitation static etc., will affect and disturb audio signal transmitted to the in-dash vehicle FM radio receiver.

In-vehicle FM wireless link performance can be improved by increasing radiated power. Howevr, FM transmitters put out no more RF power then complies with the regulations in Part 15 of the FCC rules for low-power, non-licensed transmitter. The field strength must be limited to 250 microvolts per meter at a distance of 3 meters from the antenna.

FIG. 1a, lb is a major block diagram of the conventional car audio system having the auxiliary SDARS receiver. FIGS. 1a, 1b show a vehicle 10 equipped with conventional in-dash AM/FM radio 70 with external (or on-glass) antenna 40. A novel Satellite Digital Audio Radio Services(SDARS; Satellite Digital Audio Radio Services) utilizing a satellite transmitter 20 and an on-roof mount satellite antenna 50 connected through RF coaxial cable 51 with on-board SDARS receiver 60.

Usually SDARS receiver 60 and satellite antenna 50 are auxiliary aftermarket installed. Add-on SDARS receiver 60 has standard (stereo analog, digital or both) audio signal output. SDARS radio can be connected into car stereo 80 via the AUX input of in-dash AM/FM radio 70 using hard-wired audio cable system 61 and 71.

A system for providing a wireless connection through the adapter 90 in accordance with the present invention is depicted in FIG. 2. Block diagram of a proposed adapter is shown in FIG. 3.

As shown in FIG. 2 adapter can be used in two modes: first-wireless mode (FIG. 2a) dedicated for pure wireless connection between SDARS receiver output and in-dash AM/FM radio 70 through the stationary antenna 40 and in adapter embedded antenna 92. Second mode-adapter 90 can be used as a wired transmitter/modulator. In this mode (FIG. 2b) in-dash AM/FM radio antenna input connected to the adapter RF FM output 91 through RF cable 91. Stationary car antenna 90 also connected to the adapter input 99.

### SUMMARY OF THE INVENTION

In view of the above problems associated with the prior art, it is an object of this invention to provide improved an adapter equipped in between the auxiliary SDARS receiver and in-dash vehicle AM/FM radio. This adapter combines together a wireless FM communication links and a hard-wired RF link.

In certain instances, it is preferable to eliminate hard wiring and electrical conductors between SDARS radio and in-dash AM/FM radio. For example in case of portable, “Plug-and-Play” SDARS radios in vehicle installation. Howevr, for the situations when there are high environmental RF noise or FM wireless link destroyed by the interference with commercial broadcast FM station signals link performance will be improved by instant switching from wireless link to the transmission through RF cable.

There are many situations in which the present invention is particularly advantageous. Proposed adapter combines advantage from both wireless and hard-wired link sides. Especially, transmission of FM modulated signal into the in-dash AM/FM radio tuner through the RF coaxial cable provides superior RF signal and stereo audio quality. The user selects one of these modes with respect to sound quality. The adapter schematics have to provide instant mode switching with minimum manipulation. The adapter has FM modulator, RF power amplifier and embedded loop antenna, and switches between embedded antenna and external RF cable output.

### BRIEF DESCRIPTION OF THE DRAWINGS

FIGS. 1a, 1b are a perspective view for the major blocks of conventional in-vehicle audio system with the auxiliary SDARS receiver;

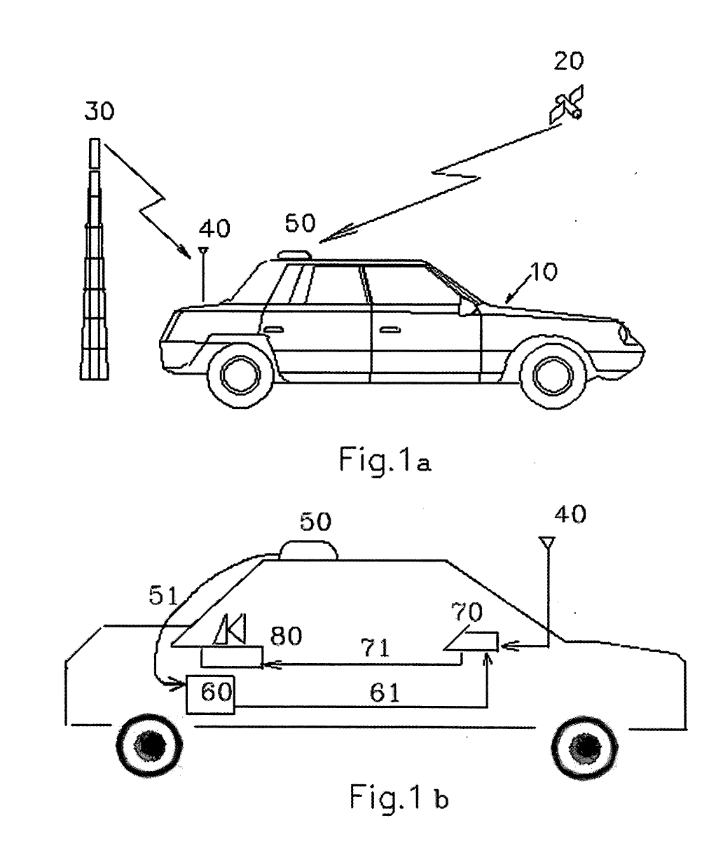

FIGS. 2a, 2b illustrate the car installation for the system in accordance with an embodiment of the present invention;

FIG. 3 is a block diagram for the proposed two-modes adapter;

### DETAILED DESCRIPTION OF THE PREFERRED EMBODIMENTS

Referring now to drawings, various preferred embodiments of the present invention will be described.

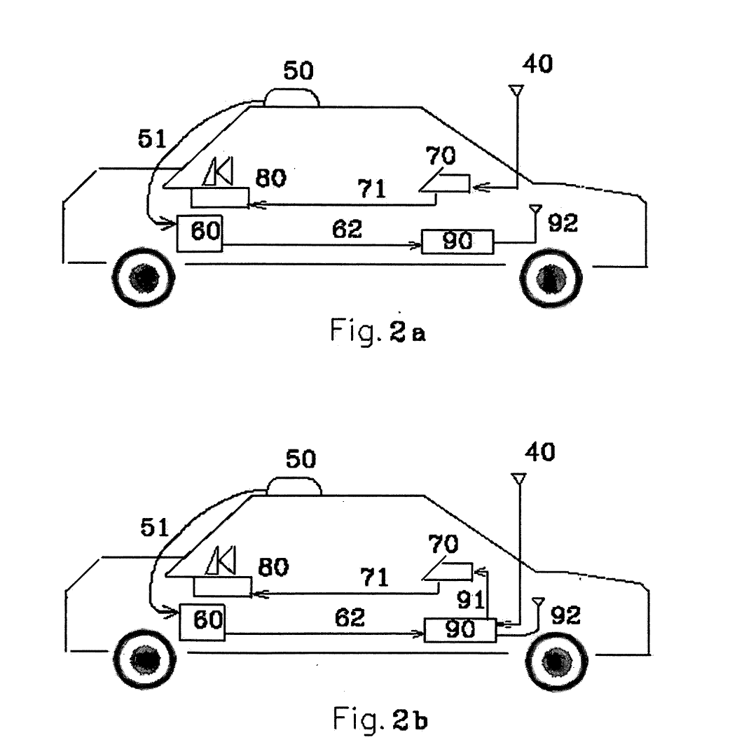

FIGS. 2a, 2b illustrate the car installation for the system in accordance with an embodiment of the present invention. FIGS. 2a, 2b show a vehicle 10 equipped with convention (OEM installation) in-dash AM/FM radio 70 with external (or on-glass) antenna 40. A novel Satellite Digital Audio Radio Services (SDARS; Satellite Digital Audio Radio Services) utilizing a satellite transmitter 20 and an on-roof mount satellite antenna 50 connected through RF coaxial cable 51 with on-board SDARS receiver 60. Usually SDARS receiver 60 and satellite antenna 50 are auxiliary aftermarket installed. Add-on SDARS receiver 60 has standard (stereo analog, digital or both) audio signal output.

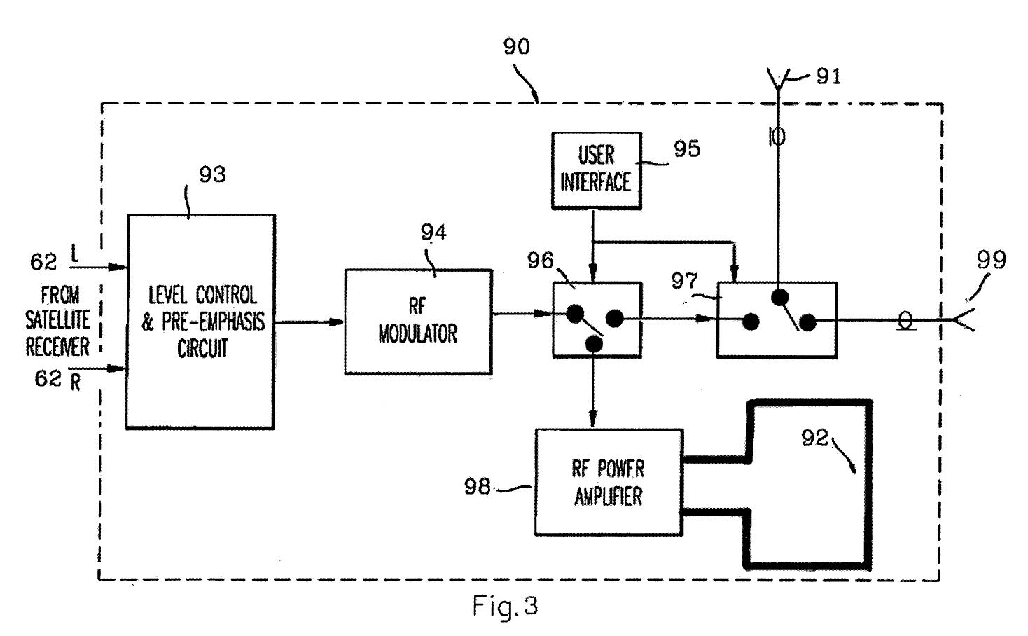

The existing SDARS radio can be connected into car stereo 80 via the AUX input of in-dash AM/FM radio 70 using hard-wired audio cable system 61 and 71. On the other side, this invention provides a system of wireless connection to AM/FM radio 70 through the adapter. A system for providing a wireless connection through the adapter 90 in accordance with the present invention is depicted in FIGS. 2a, 2b. A block diagram of a proposed adapter is shown in FIG. 3.

As shown in FIG. 2, the adapter can be used in two modes: first-wireless mode (FIG. 2a) dedicated for pure wireless connection between SDARS receiver output and in-dash AM/FM radio 70 through the stationary antenna 40 and in adapter embedded antenna 92.

Second mode—the adapter can be used as a wired transmitter/modulator. In this mode (FIG. 2b), in-dash AM/FM radio antenna input connected to the adapter RF FM output 91 through RF cable. Stationary car antenna 40 is also connected to the adapter input 99.

As shown in FIG. 3, in order to provide wireless mode (FIG. 2a), user interface unit 95 allows to switch in-dash AM/FM radio antenna input between stationary car antenna 40 and modulator RF output 91. Namely, the first RF switch 96 is connected to input of the RF low power amplifier 98. When AM/FM radio antenna input connected to modulator RF output 91 AM/FM radio can receive RF signal only from auxiliary SDARS receiver 60 with high fidelity because wired connection through cable 91 and disconnect unwanted, interference signal from antenna 40. In this switches position, as the signal transmitted from SDARS receiver output to RF modulator, the first RF switch 96 and RF low-power amplifier through the level controller and pre-emphasis circuits 93, the adapter has been used as modulator only.

As shown in FIG. 3, in order that the adapter is used as wireless FM link, user interface unit 95 also allows connection in-dash AM/FM radio antenna input directly to the stationary car antenna 40. That is, the second RF switch 97 is connected to input of the adapter and the first RF switch 96 is connected to RF power amplifier 98. In this position signal from RF modulator will be amplified by RF power amplifier unit 98 and radiated from embedded antenna 92. In this connection AM/FM radio can to receive RF signal from AM/FM station and from auxiliary SDARS receiver 60 too.

In accordance with an aspect of the present invention, the interface adapter 90 can be easily reconfigured and implemented as a pure wireless FM transmitter or as a wired transmitter/modulator. This flexibility is advantageous and desirable to provide a method for aftermarket SDARS receiver 60 installation in variety of in-vehicle audio 80 and in-dash AM/FM radio 70 systems.

Furthermore, SDARS receivers as a digital radio have to provide a digital audio output signal, not only analog. Also a novel in-dash AM/FM radio can be a Digital Audio Broadcast (DAB) compatible systems, like in-band on-channel (IBOC) system as standard for USA, which use regular AM/FM radio frequencies to broadcast digital audio signals. In some embodiments of the present invention, it may be desirable to use adapter 90 with digital DAB compatible RF modulator unit 94, not like analog stereo FM modulator. It should be noted that the adapter 90 structure and two mode adapter application variety did not depend analog or digital audio signal have to be transmitted form SDARS receivers to the car stereo through in-dash AM/FM radio.

Although the invention has been described and illustrated in the above description and drawings, it is understood that this description is by example only and that numerous changes and modifications can be made by those skilled in the art without departing from the true spirit and scope of the this invention.

As described above, The adapter in accordance with this invention can provide high quality of link performance by instant switching from wireless link to wired link through RF cable in case that there is high environmental RF noise or even if FM wireless link is destroyed by interfering of FM commercial broadcast station signals.

Also, the adapter of this invention combines advantages both for wire and wireless links. Specially, this adapter provides excellent FM modulated signal and stereo audio performance to in-dash board AM/FM radio through RF coaxial cable

1. A adapter for providing audio signals to car stereo through a in-dash board AM/FM radio receiver from an auxiliary SDARS radio comprising:
an adapter audio input for receiving said audio signals from said auxiliary SDARS radio;
an adapter RF output for cable connection to said AM/FM radio antenna input;
a RF antenna adapter input for cable connection to the car AM/FM antenna;
an embedded antenna;
RF low power amplifier loaded to said embedded antenna;
RF modulator for RF signal modulation by said audio signal from said adapter audio input;
First RF switch with control from user interface to connect said RF modulator output to the said RF power amplifier input or to the said adapter RF output;
Second RF switch with control from user interface to connect said adapter RF output to said antenna RF input or to the said RF modulator output.

2. An adapter as claimed in claim 1 wherein when said adapter configured for purewireless mode and operable to transmit said audio signals to said AM/FM radio through said embedded antenna and said car AM/FM antenna wireless link and further comprising:
said auxiliary SDARS radio connected to said adapter audio input;
said car AM/FM antenna connected to said AM/FM radio antenna input;
said first RF switch provide connection between said RF modulator output to the said
RF low power amplifier with RF signal radiation by said embedded antenna.

3. An adapter as claimed in claim 1 wherein when said adapter configured for wired modulator/transmitter mode and further comprising:
said car AM/FM antenna connected to said RF antenna adapter input;
said adapter RF output connected to said AM/FM radio antenna input;
in said modulator mode said first RF switch and said second RF switch provide connection said RF modulator output to the said AM/FM radio antenna input, said car AM/FM antenna disconnected;
in said transmitter mode said second RF switch provide connection between said car AM/FM antenna and said AM/FM radio antenna input; in said transmitter mode said first RF switch provide connection between said
RF modulator output to the said RF low power amplifier with RF signal radiation by said embedded antenna.

4. The system of claim 2 and claim 3 further comprising: said in-dash board AM/FM radio receiver is a Digital Audio Broadcast (DAB) compatible systems which use regular AM/FM radio frequencies;
said RF modulator provide DAD compatible RF signal modulation by digital audio signal from said auxiliary SDARS radio.
